(19) United States
(12) Patent Application Publication
(10) Pub. No.: US 2026/0121608 A1
(43) Pub. Date: Apr. 30, 2026

(54) HIGHER ORDER MODE BULK ACOUSTIC WAVE DEVICE WITH FRAME STRUCTURE

(71) Applicant: Skyworks Global Pte. Ltd., Singapore (SG)

(72) Inventors: Kwang Jae Shin, Yongin-si (KR); Stefan Bader, Fort Collins, CO (US); Zongliang Cao, Irvine, CA (US); Yanbo He, Irvine, CA (US)

(21) Appl. No.: 19/365,923

(22) Filed: Oct. 22, 2025

Related U.S. Application Data
(60) Provisional application No. 63/826,187, filed on Jun. 18, 2025.
(60) Provisional application No. 63/711,940, filed on Oct. 25, 2024.
(60) Provisional application No. 63/711,932, filed on Oct. 25, 2024.

(51) Int. Cl. H03H 9/02; H03H 9/17; H03H 9/56

(52) U.S. Cl. CPC H03H 9/02015; H03H 9/0207; H03H 9/02086; H03H 9/173; H03H 9/568

(57) ABSTRACT

Aspects of this disclosure relate to a bulk acoustic wave having a higher order mode as a main mode. The bulk acoustic wave device includes a frame structure in a frame region and a piezoelectric layer that has an engineered region in at least part of the frame region. Related acoustic wave filters, multiplexers, radio frequency modules, radio frequency systems, wireless communication devices, methods of manufacture, and methods of filtering are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/711,940, filed October 25, 2024 and titled “BULK ACOUSTIC WAVE DEVICE WITH FRAME STRUCTURE HAVING HIGHER ORDER MODE AS MAIN MODE,” claims the benefit of priority of U.S. Provisional Application No. 63/711,932, filed October 25, 2024 and titled “FRAME MODE SUPPRESSION IN BULK ACOUSTIC WAVE DEVICE HAVING HIGHER ORDER MODE AS MAIN MODE,” claims the benefit of priority of U.S. Provisional Application No. 63/826,187, filed June 18, 2025 and titled “FRAME MODE SUPPRESSION IN HIGHER ORDER MODE BULK ACOUSTIC WAVE DEVICE WITH MULTIPLE PIEZOELECTRIC LAYERS,” the disclosures of each of which are hereby incorporated by reference in their entireties and for all purposes.

### BACKGROUND

### Technical Field

The disclosed technology relates to bulk acoustic wave devices. Embodiments of this disclosure relate to bulk acoustic wave devices with a piezoelectric layer with an engineered region and a higher order mode as a main mode.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device having a main acoustically active region and a frame region. The bulk acoustic wave device has a higher order mode as a main mode. The bulk acoustic wave device includes a frame structure in the frame region, electrodes including a first electrode and a second electrode, and a piezoelectric layer positioned between the first electrode and the second electrode in the main acoustically active region and the frame region. The piezoelectric layer has an engineered region in at least part of the frame region. The piezoelectric layer contributes to exciting the higher order mode as the main mode.

The frame structure can include a raised frame structure and a recessed frame structure. The frame structure can include at least one of a metal raised frame structure and a dielectric raised frame structure.

The bulk acoustic wave device can include a waveguide layer at least in the main acoustically active region. The waveguide layer can have has a thickness of λ/2, where λ is a wavelength of a bulk acoustic wave generated by the bulk acoustic wave device in an operating mode. The waveguide layer can include a passivation layer. The second electrode can be positioned between the piezoelectric layer and the passivation layer. The passivation layer can include silicon dioxide. A thickness of the passivation layer can be in a range from 1.5 to 4 times a thickness of the second electrode. The bulk acoustic wave device can include a second passivation layer, where the first electrode is positioned between the piezoelectric layer and the second passivation layer. A thickness of the second passivation layer can be in a range from 1.5 to 4 times a thickness of the first electrode. The waveguide layer can include a Bragg reflector layer. The bulk acoustic wave device can include a metal layer, where the Bragg reflector layer is positioned between the first electrode and the metal layer, and the first electrode is positioned between the piezoelectric layer and the Bragg reflector layer. A thickness of the metal layer can be in a range between 1.2 to 2 times a thickness of the second electrode. The bulk acoustic wave device can include a second metal layer and a second Bragg reflector layer, where the second Bragg reflector layer is positioned between the second electrode and the second metal layer. A thickness of the metal layer and a thickness of the second metal layer can each be greater than a thickness of the first electrode.

The bulk acoustic wave device can include a second piezoelectric layer at least in the main acoustically active region. The second piezoelectric layer can have a second engineered region in the frame region. The bulk acoustic wave device can include a metal layer positioned between the piezoelectric layer and the second piezoelectric layer. The piezoelectric layer can have a first c-axis and the second piezoelectric layer have a second c-axis with a different orientation than the first c-axis. The first c-axis and the second c-axis can be oriented in substantially opposite directions. The piezoelectric layer can have a first c-axis and the second piezoelectric layer have a second c-axis, where the first c-axis and the second c-axis have a same orientation.

The higher order mode can be a second overtone mode. The higher order mode can be a third overtone mode.

The piezoelectric layer can have an effective piezoelectric coefficient in the engineered region that is less than 50% of a magnitude of an effective piezoelectric coefficient of the piezoelectric layer in the main active region.

The bulk acoustic wave device can include a seed layer positioned between the first electrode and engineered region of the piezoelectric layer. The bulk acoustic wave device can be free from the seed layer in the main acoustically active region.

Another aspect of this disclosure is a bulk acoustic wave device having a main acoustically active region and a frame region. The bulk acoustic wave device includes electrodes including a first electrode and a second electrode; a piezoelectric layer between the first electrode and the second electrode, the piezoelectric layer having an engineered region in the frame region; a frame structure in the frame region; and a waveguide layer at least in the main acoustically active region, and the piezoelectric layer and the waveguide layer having thicknesses contributing to exciting a higher order mode as a main mode of the bulk acoustic wave device.

Another aspect of this disclosure is a bulk acoustic wave device having a main acoustically active region and a frame region. The bulk acoustic wave device includes electrodes including a first electrode and a second electrode; a piezoelectric layer between the first electrode and the second electrode, the piezoelectric layer having an engineered region in the frame region; a frame structure in the frame region; and a non-piezoelectric layer at least in the active region, the non-piezoelectric layer being in acoustic communication with the piezoelectric layer to excite a higher order mode as a main mode of the bulk acoustic wave device.

Another aspect of this disclosure is a bulk acoustic wave device having an active region and a frame region. The bulk acoustic wave device includes electrodes including a first electrode and a second electrode; a first piezoelectric layer between the first electrode and the second electrode, the first piezoelectric layer having an engineered region in at least part of the frame region; a second piezoelectric layer between the first electrode and the second electrode; and a frame structure in the frame region.

The first piezoelectric layer can be stacked with the second piezoelectric layer between the first electrode and the second electrode. The first piezoelectric layer can have a first c-axis with a substantially opposite orientation than a second c-axis of the second piezoelectric layer.

The second piezoelectric layer can have a second engineered region in the frame region.

The bulk acoustic wave device can include a metal layer positioned between the first piezoelectric layer and the second piezoelectric layer. The metal layer can be an interposer. The metal layer can be an electrode. The first piezoelectric layer can be stacked with the second piezoelectric layer between the first electrode and the second electrode. The first piezoelectric layer can have a first c-axis having substantially a same orientation as a second c-axis of the second piezoelectric layer. The bulk acoustic wave device can include a second metal layer and a third piezoelectric layer between the second electrode and the second metal layer.

The bulk acoustic wave device can have a higher order mode as a main mode. The higher order mode can be a second overtone mode. The higher order mode can be a third overtone mode.

The first piezoelectric layer can have an effective piezoelectric coefficient in the engineered region that is less than 50% of a magnitude of an effective piezoelectric coefficient of the first piezoelectric layer in the active region.

The frame structure can include a metal raised frame layer and an oxide raised frame layer.

The bulk acoustic wave device can include an acoustic reflector, where the second piezoelectric layer positioned between the first piezoelectric layer and the acoustic reflector.

Another aspect of this disclosure is a bulk acoustic wave device having an active region and a frame region. The bulk acoustic wave device includes electrodes including a first electrode and a second electrode; a metal layer; a first piezoelectric layer between the first electrode and the metal layer, the first piezoelectric layer having an engineered region in the frame region; a second piezoelectric layer between the metal layer and the second electrode; and a frame structure in the frame region.

The frame structure can include a raised frame structure and a recessed frame structure. The frame structure can include a metal raised frame structure and/or a dielectric raised frame structure.

The first piezoelectric layer can have a first c-axis and the second piezoelectric layer can have a second c-axis oriented in substantially the same direction as the first c-axis.

The first piezoelectric layer can have a first c-axis and the second piezoelectric layer can have a second c-axis different from the first c-axis. The first c-axis and the second c-axis can be oriented in substantially opposite directions.

A material of the first piezoelectric layer and a material of the second piezoelectric layer can be the same. The material can include aluminum nitride.

The first piezoelectric layer can be doped with scandium.

Another aspect of this disclosure is a bulk acoustic wave device having an active region and a frame region. The bulk acoustic wave device includes an acoustic reflector; electrodes including a first electrode and a second electrode; a metal layer; a first piezoelectric layer between the first electrode and the metal layer; a second piezoelectric layer between the metal layer and second electrode, the second piezoelectric layer having an engineered region in the frame region, and the first piezoelectric layer being positioned between the second piezoelectric layer and the acoustic reflector; and a frame structure in the frame region.

The bulk acoustic wave device can be a high even mode bulk acoustic wave device.

The bulk acoustic wave device can be a high odd mode bulk acoustic wave device.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave device in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave (BAW) device having a higher order mode as a main mode according to an embodiment.

FIG. 1B is a top plan view of a portion of the BAW device of FIG. 1A.

FIG. 2 is a schematic cross-sectional side view of a BAW device according to another embodiment.

FIG. 3A is a schematic cross-sectional side view of a BAW device according to another embodiment.

FIG. 3B is a schematic cross-sectional side view of a BAW device according to another embodiment.

FIG. 3C is an enlarged view of a portion of a frame region in a peripheral region of the BAW device shown in FIG. 3B.

FIG. 3D shows an example stack in a frame region of a BAW device according to an embodiment.

FIG. 3E shows another example stack in a frame region of a BAW device according to an embodiment.

FIG. 4A is a schematic cross-sectional side view of a BAW device according to an embodiment.

FIG. 4B is a schematic cross-sectional side view of a BAW device according to another embodiment.

FIG. 4C is a schematic cross-sectional side view of a BAW device according to another embodiment.

FIG. 4D is a schematic cross-sectional side view of a BAW device according to another embodiment.

FIG. 5A is a schematic cross-sectional side view of a BAW device according to another embodiment.

FIG. 5B is a diagram showing a theoretical wave displacement in the BAW device of FIG. 5A.

FIG. 5C is a diagram showing a theoretical wave displacement in a BAW device that includes four electrodes and three piezoelectric layers therebetween.

FIG. 5D is a diagram showing a theoretical wave displacement in a BAW device that includes five electrodes and four piezoelectric layers therebetween.

FIG. 5E is a schematic cross-sectional side view of a BAW device according to another embodiment.

FIG. 5F is a schematic cross-sectional side view that includes an end portion of a BAW device according to an embodiment.

FIG. 5G is a schematic cross-sectional side view that includes another end portion of the BAW device of FIG. 5E.

FIG. 6A is a schematic diagram of a ladder filter that includes one or more BAW resonators according to an embodiment.

FIG. 6B is schematic diagram of a band pass filter.

FIGS. 7A, 7B, 7C, and 7D are schematic diagrams of multiplexers that include a filter with one or more BAW resonators according to an embodiment.

FIGS. 8, 9, and 10 are schematic block diagrams of modules that include a filter with one or more BAW resonators according to an embodiment.

FIG. 11 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Bulk acoustic wave (BAW) resonators with higher resonant frequencies are desired for filters to filter higher frequency radio frequency (RF) signals, such as ultra-high bands above 5 gigahertz (GHz). BAW resonators often use a fundamental mode as a main mode. When using fundamental mode to achieve higher resonant frequency, the BAW resonator size becomes smaller and the piezoelectric layer becomes thinner when maintaining the same impedance.

The piezoelectric layer thickness can scale with 1/f, and the desired capacitance per branch can also scale with 1/f for achieving the same impedance, where f is resonant frequency. Consequently, the BAW resonator area can scale with 1/f². As one example, reducing resonant frequency by a factor of two (2) can increase piezoelectric layer thickness by a factor of two (2) and area by a factor of four (4) for achieving the same impedance. BAW resonators with smaller physical size can have a lower quality factor (Q) than larger sized resonators.

The size reduction of a BAW resonator for scaling for higher resonant frequency may help with reducing filter size. However, there are a variety of technical challenges associated with smaller sized BAW resonators with thinner piezoelectric layers, such as one or more of more spurious modes, increased edge energy leakage, reduced power handling capabilities and/or degraded ruggedness, or challenges in manufacturing and/or trimming (e.g., frequency trimming). During operation of the BAW device, heat can be generated, which can alter the material properties (e.g., stiffness or Young’s modulus) of the layers in the BAW device such as the piezoelectric layer in a manner that can negatively affect the performance of the BAW device. Such consequences may be more pronounced with a thinner piezoelectric layer.

A BAW resonator can use a higher order mode or an overtone mode as a main mode instead of a fundamental mode. The overtone mode can be excited due to, for example, structural asymmetry of a BAW device stack over an acoustic reflector. By exciting the overtone mode, a higher resonant frequency can be achieved than by using the fundamental mode as the main mode. For example, an overtone mode can have a resonant frequency in a range from about 1.5 to about 2.5 times the fundamental mode. Although BAW resonators that are structured to use the overtone mode as the main mode can have various advantages, such a BAW resonator may still experience lateral energy leakage from a main acoustically active region of a BAW device, which can lead to losses.

Increasing the Q of a given BAW resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices disclosed herein can achieve improved performance by engineering a region of a piezoelectric layer. Such engineering can degrade crystallinity of the engineered region of the piezoelectric layer.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of layer that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. The main acoustically active region can be a region of a BAW device that generates a main resonant frequency. The main acoustically active region can be free from frame structures. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. A raised frame structure can create a resonance at a frequency that is below a resonant frequency of the main acoustically active region of the BAW device. This resonance can be below a main resonant frequency of the BAW device. A resonance associated with the raised frame structure can be referred to as a raised frame mode. The raised frame mode can be undesirable in certain applications.

This disclosure provides technical solutions that can suppress and/or eliminate raised frame modes in BAW resonators that are structured to use a higher order mode or overtone mode as the main mode. At the same time, technical solutions disclosed herein can maintain a desired electromechanical coupling coefficient (kt²) and significantly increase a Q of such BAW devices. BAW devices disclosed herein can achieve significant performance improvements over other BAW devices. Filters that include BAW devices disclosed herein can provide improved performance in a variety of applications, such as but not limited to fifth generation (5G) New Radio (NR) applications.

Aspects of this disclosure relate to bulk acoustic wave devices having a higher order mode as a main mode. A bulk acoustic wave device can have a main acoustically active region and a frame region. The bulk acoustic wave device can include a first electrode, a second electrode, and a piezoelectric layer. A frame structure, such as a raised frame structure and/or a recessed frame structure, can be positioned in the frame region to reduce lateral energy leakage from the main acoustically active region. At least a portion of the piezoelectric layer in the frame region can be engineered to be less piezoelectric to suppress the frame mode.

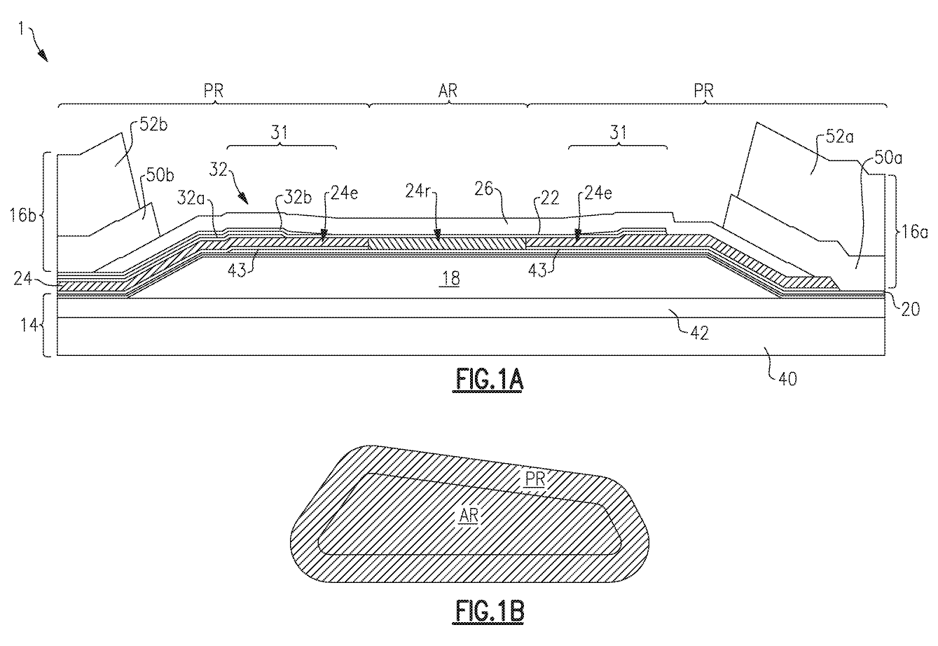

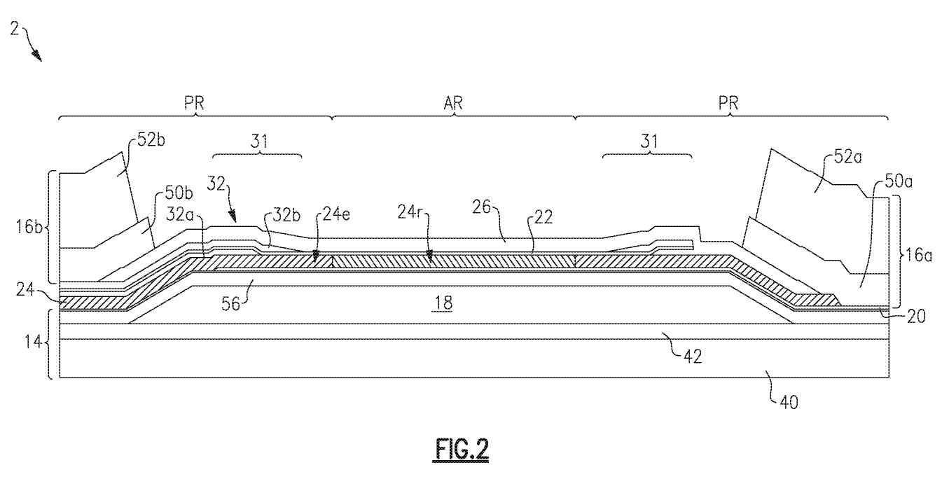

FIG. 1A is a schematic cross-sectional side view of a BAW device 1 having a higher order mode as a main mode according to an embodiment. A higher order mode can be a mode that is higher order than the fundamental mode. The main mode can be a mode associated with a highest electromechanical coupling coefficient (kt²) among modes generated by the BAW device 1. The main mode can be an operating mode of the BAW device 1 that is used for a filter that includes the BAW device 1. For example, the main mode can be an operating mode of the BAW device 1 that is used for a passband of a bandpass filter that includes the BAW device 1. FIG. 1B is a top plan view of the BAW device 1 of FIG. 1A. The BAW device 1 can include an acoustic reflector (e.g., a cavity 18), a first electrode 20, a second electrode 22, and a piezoelectric layer 24. The piezoelectric layer 24 includes an engineered region 24e. A region of the piezoelectric layer 24 that is not engineered to reduce its piezoelectricity can be referred to as a regular region 24r of the piezoelectric layer 24. A passivation layer 26 can be provided over the second electrode 22.

The passivation layer 26 is an example of a waveguide layer. For example, the passivation layer 26 can be a vertical wave guide that can guide waves in a vertical direction. In some embodiments, the passivation layer 26 can be a silicon dioxide layer. The passivation layer 26 can be any other suitable passivation layer, such as aluminum oxide, silicon carbide, aluminum nitride, silicon nitride, silicon oxynitride, or the like. The passivation layer 26 can include a dielectric material. The passivation layer 26 is thicker in the BAW device 1 than in certain BAW devices where a fundamental mode is the main mode. The thickness of the passivation layer 26 can contribute to exciting the higher order mode as the main mode in the BAW device 1. The higher order mode that is the main mode of the BAW device 1 can be a second overtone mode. In some embodiments, the passivation layer 26 can provide temperature compensation and be referred to as a temperature compensation layer. For example, the passivation layer 26 can have a positive temperature coefficient of frequency to compensate for a negative temperature coefficient of frequency of the piezoelectric layer 24 and bring the temperature coefficient of frequency of the BAW device 1 closer to zero.

The passivation layer 26 can have a thickness that enables the BAW device 1 to have a higher order mode as a main mode. The thickness of the passivation layer 26 can be λ/2 or approximately λ/2, where λ is a wavelength of a bulk acoustic wave generated by the BAW device 1 in an operating mode. The operating mode can be the mode used for a filter than includes the BAW device 1. The operating mode can be the main mode of the BAW device 1. The wavelength λ can be represented by acoustic velocity divided by frequency. The acoustic velocity can depend at least in part on the material in which a wave propagates. For example, an acoustic velocity in silicon dioxide (SiO₂) can be about 5500 m/s, an acoustic velocity in aluminum nitride (AlN) can be about 11,000 m/s, an acoustic velocity in tungsten (W) can be about 5200 m/s, and an acoustic velocity in ruthenium (Ru) can be about 6500 m/s under certain conditions. The combined thickness of the piezoelectric layer 24, the first electrode 20, and the second electrode 22 can also be λ/2 or approximately λ/2. The passivation layer 26 has a thickness that is greater than a thickness of the first electrode 20 and/or a thickness of the second electrode 22. The thickness of the passivation layer 26 can be more than 3 times the thickness of the first electrode 20 and/or the thickness of the second electrode 22. The thickness of the passivation layer 26 can be in a range from 1.5 to 4 times the thickness of the first electrode 20 and/or the thickness of the second electrode 22. In some embodiments, the thickness of the passivation layer 26 can be greater than a thickness of the piezoelectric layer 24. For example, the thickness of the passivation layer 26 can be in a range from 1 to 1.3 times the thickness of the piezoelectric layer 24.

A change in the thickness of the second electrode 22 can have a significantly larger impact on a change in resonant frequency than the same change in the thickness of the passivation layer 26. This can be due to differences in mass loading, as the second electrode 22 may have a higher density than the passivation layer 26. More generally, a change in thickness of a denser second electrode 22 can have a larger impact on resonant frequency of the BAW device 1 than the same change in thickness in a less dense passivation layer 26. In the BAW device 1, an overtone mode (e.g., a second overtone mode, a third overtone mode, or a mode higher than the third overtone mode) can be excited as a main mode for a variety of combinations of layer thicknesses in an asymmetric BAW material stack, in which the main mode has the highest kt² of the modes of the BAW device 1.

A region where the first electrode 20, the second electrode 22, and the piezoelectric layer 24 overlap over the acoustic reflector (e.g., the cavity 18) and generate an acoustic wave can define an acoustically active region AR of the BAW device 1. The first electrode 20, the second electrode 22, and the regular region 24r of the piezoelectric layer 24 overlap in the acoustically active region AR of the BAW device 1. The acoustically active region AR can include a main acoustically active region. The main acoustically active region does not overlap and/or is free from a frame structure. In the BAW device 1, the main acoustically active region spans the active region AR. In some other applications, a recessed frame structure can be in the active region and the main acoustically active region can be the part of the active region that does not overlap and/or is free from the recessed frame structure. The BAW device 1 can include a frame region, where a frame structure 31 is positioned, outside of the main acoustically active region, and a peripheral region PR outside of the acoustically active region AR. The frame structure 31 of the BAW device 1 includes the raised frame structure 32 that overlaps with both the first electrode 20 and the second electrode 22. The piezoelectric layer 24 in the peripheral region PR is engineered and the engineered region 24e of the piezoelectric layer 24 has a lower magnitude effective piezoelectric coefficient than the regular region 24r of the piezoelectric layer 24 in the acoustically active region AR. The frame region and the peripheral region PR can at least partially overlap.

The BAW device 1 can include the frame structure 31 in the frame region. The frame structure 31 can include a raised frame structure 32 and/or a recessed frame structure (not shown). The recessed frame structure can be positioned in the acoustically active region AR or be positioned in the peripheral region PR that is outside of the acoustically active region AR.

The engineered region 24e of the piezoelectric layer 24 can have a lower magnitude effective piezoelectric coefficient than the regular region 24r of the piezoelectric layer 24 in the acoustically active region AR. For example, the engineered region 24e of the piezoelectric layer 24 can have an effective piezoelectric coefficient magnitude that is less than 50%, less 30%, or less than 10% of the effective piezoelectric coefficient magnitude of the regular region 24r of the piezoelectric layer 24 in the acoustically active region AR. The engineered region 24e of the piezoelectric layer 24 is materially and structurally different from a material layer that is not engineered or an originally non-piezoelectric material layer. Even though engineered regions (e.g., the engineered region 24e) of BAW devices of this disclosure may have little or no piezoelectricity, such an engineered region can be considered part of a piezoelectric layer of a BAW device of this disclosure.

The effective piezoelectric coefficient can be an aggregate piezoelectric coefficient for the entire engineered region 24e. The aggregate magnitude of the piezoelectric polarization vectors in the engineered region 24e should be less than the magnitude in the regular region 24r. The lower magnitude effective piezoelectric coefficient can be a result of the non-aligned nature of piezoelectric material crystal orientations within the engineered region 24e causing a lower aggregate magnitude of the piezoelectric polarization vectors.

The engineered region 24e can be formed in any suitable manner. In some embodiments, a uniform piezoelectric material can be deposited and then the engineered region 24e of the piezoelectric material can be modified to be less piezoelectric than the regular region 24r. For example, ions can be implanted to modify the structure and properties of the piezoelectric material by ion implantation to form the engineered region 24e. In such embodiments, the piezoelectric material can be engineered from a side opposite the first electrode 20.

Alternatively or additionally, a seed layer 43 can be positioned over portions of the first electrode 20 where the engineered region 24e is to be formed. The seed layer 43 can cause the piezoelectric layer 24 to be engineered in the engineered region 24e. The seed layer 43 can be a material that has poor crystallinity or is crystalline with a poor lattice match to the piezoelectric film applied over the seed layer 43. The piezoelectric layer 24 in the engineered region 24e over the seed layer 43 can have relatively poor bulk piezoelectric properties compared to the piezoelectric layer 24 in the regular region 24r. The seed layer 43 can be directly over the first electrode 20 in certain applications. The seed layer 43 can be a layer formed by atomic layer deposition, for example. The seed layer 43 can include, but is not limited to, an oxide, a nitride, a carbide, a carbon structure (e.g., graphene or diamond), a boride, or any suitable combination thereof. In certain applications, the seed layer 43 can include one or more of aluminum oxide, silicon, silicon carbide, doped aluminum nitride, undoped aluminum nitride, aluminum, fused silica, boron nitride, diamond, silicon oxycarbide glass, silicon oxynitride glass, boron carbide, graphene, beryllium oxide, gallium nitride, indium nitride, silicon nitride, scandium nitride, or the like. In some embodiments, the seed layer 43 can have a thickness that is in a single digit nanometer range. In some embodiments, the seed layer 43 can have a thickness that is in a range from 10 nanometers to 100 nanometers.

The effective piezoelectric coefficient can be an effective piezoelectric coupling coefficient (e₃₃), for example. The engineered region 24e of the piezoelectric layer 24 can suppress the frame mode associated with the raised frame structure 32. BAW devices with an engineered region of a piezoelectric layer and a frame structure (e.g., a raised frame structure 32 and/or a recessed frame structure) disclosed herein can enable frame mode suppression, transverse mode suppression, and lateral mode suppression.

A boundary or border between the regular region 24r and the engineered region 24e of the piezoelectric layer 24 can be the boundary or border between the active region AR and the peripheral region PR, respectively. The border between the regular region 24r and the engineered region 24e can be adjusted to have a more engineered region area +ERA or a less engineered region area -ERA relative to the BAW device 1 shown in FIG. 1A.

The first electrode 20 can be referred to as a lower electrode. The first electrode 20 can have a relatively high acoustic impedance. The first electrode 20 can include molybdenum (Mo), tungsten (W), ruthenium (Ru), chromium (Cr), iridium (Ir), platinum (Pt), or any suitable alloy and/or combination thereof. Similarly, the second electrode 22 can have a relatively high acoustic impedance. The second electrode 22 can include Mo, W, Ru, Cr, Ir, Pt, or any suitable alloy and/or combination thereof. The second electrode 22 can be formed of the same material as the first electrode 20 in certain applications. The second electrode 22 can be referred to as an upper electrode. The thickness of the first electrode 20 can be approximately the same as the thickness of the second electrode 22 in the acoustically active region AR of the BAW device 1.

The piezoelectric layer 24 can include a suitable material such as, but not limited to, aluminum nitride (AlN), zinc oxide (ZnO), or lead zirconium titanate (PZT). In certain applications, the piezoelectric layer 24 can be an AlN layer. The piezoelectric material can be doped or undoped. For example, an AlN-based piezoelectric layer can be doped with any suitable dopant, such as scandium (Sc), chromium (Cr), magnesium (Mg), sulfur (S), yttrium (Y), silicon (Si), germanium (Ge), oxygen (O), hafnium (Hf), zirconium (Zr), titanium (Ti), or the like. In certain applications, the piezoelectric layer 24 can be AlN based layer doped with Sc. According to some of these applications, the piezoelectric layer 24 of the BAW device 1 can be an AlN based piezoelectric layer doped with 10% to 20% Sc. Doping the piezoelectric layer 24 can adjust the resonant frequency. Doping the piezoelectric layer 24 can increase the kt² of the BAW device 1. Doping to increase the kt² can be advantageous at higher frequencies where kt² can be degraded. In certain applications, two or more piezoelectric layers can be implemented with any suitable principles and advantages disclosed herein.

The frame structure 31 can be configured to suppress the transverse mode. The raised frame structure 32 can reduce or impede propagation of the transverse mode. As illustrated in FIG. 1A, the raised frame structure 32 is a multi-layer raised frame structure that includes a raised frame structure 32a and a raised frame structure 32b. The raised frame structure 32b can include a material that has a relatively high mass density. For instance, the raised frame structure 32b can include molybdenum (Mo), tungsten (W), ruthenium (Ru), the like, or any suitable alloy thereof. In some embodiments, the raised frame structure 32b and the second electrode 22 can be formed of the same material. The raised frame structure 32b can be a metal layer. Alternatively, the raised frame structure 32b can be a suitable non-metal material with a relatively high density. The density of the raised frame structure 32b can be similar to or heavier than the density of the first electrode 20 or the second electrode 22. The raised frame structure 32a can include a low acoustic impedance material that has a lower acoustic impedance than the first electrode 20, the second electrode 22, and/or the piezoelectric layer 24. For example, the raised frame structure 32a can include a silicon dioxide (SiO₂) layer, a silicon nitride (SiN) layer, a silicon carbide (SiC) layer, or any other suitable low acoustic impedance layer. The raised frame structure 32a can be a dielectric layer. The raised frame structure 32a can be an oxide layer. For example, the raised frame structure 32 shown in FIG. 1A includes an oxide raised frame structure 32a having a width, and a metal raised frame structure 32b having a width between the acoustically active region AR and the oxide raised frame structure 32a. In some embodiments, a recessed frame structure can be provided between the acoustically active region AR and the metal raised frame structure 32b. According to some other embodiments, a recessed frame structure can be included in the acoustically active region AR.

A frame structure can include, for example, a single layer raised frame structure, a multi-layer raised frame structure that includes two or more raised frame layers such as the illustrated raised frame structure 32, a recessed frame structure, or a combination of a raised frame structure and a recessed frame structure. As an example, a frame structure can have a multi-layer raised frame structure that includes a relatively high density layer and a relatively low acoustic impedance layer. The low acoustic impedance layer can contribute to reducing an effective kt² relative to a single high-density raised frame structure, which can reduce excitation strength of a raised frame spurious mode. As another example, a floating raised frame structure can be implemented. In the BAW device 1, the frame structure 31 is illustrated as being asymmetric about the acoustically active region AR. However, in some embodiments, the frame structure 31 can be symmetric about the acoustically active region AR.

The support structure 14 can include a support substrate 40 and an intermediate layer 42 between the support substrate and the first electrode 20. The support substrate 40 can be a semiconductor substrate. The support substrate 40 can be any other suitable support substrate, such as a substrate of quartz, silicon carbide, sapphire, glass, gallium arsenide, or any suitable ceramic (e.g., spinel, alumina, etc.).

The intermediate layer 42 can include, for example, one or more of a seed layer, a trap rich layer, a passivation layer, or one or more other suitable functional layers. In some embodiments, the intermediate layer 42 can be completely or partially omitted. In some such embodiments, a portion of the first electrode 20 can directly contact the support substrate 40. The intermediate layer 42 can be relatively thin. For example, the intermediate layer 42 is typically significantly thinner than the support substrate 40. Heat generated by the BAW device 1 can dissipate through the first electrode 20 to the support substrate 40 at a location where there is no cavity 18 between the first electrode 20 and the support substrate 40.

As shown in FIG. 1A, a first interconnect structure 16a can include one or more conductive layers such as a first conductive layer 50a and a second conductive layer 52a. Similarly, a second interconnect structure 16b can include one or more conductive layers such as a first conductive layer 50b and a second conductive layer 52b. The first conductive layers 50a, 50b and the second conductive layers 52a, 52b can each include a material suitable for interconnecting the BAW device 1 and one or more other component (e.g., another resonator) in a filter, an external component, or a ground connection. The first conductive layers 50a, 50b and/or the second conductive layers 52a, 52b can be highly conductive. For example, the first conductive layers 50a, 50b and/or the second conductive layers 52a, 52b can be more electrically conductive than the first electrode 20 and/or the second electrode 22. In some embodiments, the first conductive layers 50a, 50b and/or the second conductive layers 52a, 52b can include one or more of gold (Au), titanium (Ti), copper (Cu), aluminum (Al), or tungsten (W).

The cavity 18 (e.g., an air cavity) can be formed between the support substrate 40 and the first electrode 20. The cavity 18 is an example of an acoustic reflector. The BAW device 1 can be a film bulk acoustic wave resonator (FBAR). In some other embodiments, there can be a solid acoustic mirror in place of the cavity 18 and such a BAW device can be a BAW solidly mounted resonator (SMR).

A BAW device in accordance with principles and advantages disclosed herein can have overtone mode that is a main mode with a resonant frequency in a range from 5 GHz to 12 GHz, in a range from 5 GHz to 20 GHz, in a range from 6 GHz to 12 GHz, in a range from 12 GHz to 20 GHz, or in a range from 7 GHz to 10 GHz. In some embodiments, the BAW device in accordance with principles and advantages disclosed herein can have overtone mode that is a main mode with an anti-resonant frequency in a range corresponding to any of these ranges of the resonant frequency. BAW devices with an overtone mode as a main mode in accordance with the principles and advantages disclosed herein can be used in filters arranged to filter radio frequency signals with frequencies in a range from 5 GHz to 12 GHz. BAW devices with an overtone mode as a main mode in accordance with the principles and advantages disclosed herein can be used in filters arranged to filter radio frequency signals with frequencies in a range from 6 GHz to 12 GHz. BAW devices disclosed herein can be used to filter ultra high band signals defined in radio frequency communication standards. In certain applications, BAW devices with an overtone mode as a main mode in accordance with the principles and advantages disclosed herein can be used in filters arranged to filter radio frequency signals with frequencies in a 5G NR operating band at an upper end of Frequency Range 1 (FR1). BAW devices disclosed herein can be implemented in transmit filters, which typically have higher power handling specifications than receive filters.

The principles and advantages of the frame mode suppression disclosed herein can be implemented in any suitable BAW devices that have a higher order mode as a main mode instead of having the fundamental mode as a main mode. A BAW device can generate a higher order mode as a main mode in a variety of stack combinations of different layers in the BAW device, for example, as shown herein.

FIG. 2 is a schematic cross-sectional side view of a BAW device 2 according to an embodiment. Unless otherwise noted, the components of the BAW device 2 shown in FIG. 2 may be structurally and/or functionally the same as or generally similar to like components of other BAW devices disclosed herein. The BAW device 2 can be generally similar to the BAW device 1 shown in FIGS. 1A and 1B. In the BAW device 2 illustrated in FIG. 2, passivation layers 26, 56 contribute to exciting an overtone as a main mode.

The BAW device 2 can include an acoustic reflector (e.g., a cavity 18), a first electrode 20, a second electrode 22, and a piezoelectric layer 24. The piezoelectric layer 24 includes an engineered region 24e. A region of the piezoelectric layer 24 that is not engineered to reduce its piezoelectricity can be referred to as a regular region 24r of the piezoelectric layer 24. In certain applications, the piezoelectric layer 24 can be AlN based layer doped with Sc. According to some of these applications, the piezoelectric layer 24 of the BAW device 2 can be an AlN based piezoelectric layer doped with 5% to 15% Sc. The passivation layer 26 can be provided over the second electrode 22 and the passivation layer 56 can be provided between the first electrode 20 and the cavity 18.

The passivation layer 26 and the passivation layer 56 are examples of waveguide layers. The passivation layer 26 and the passivation layer 56 can have the same material, in some applications. In some embodiments, the passivation layer 56 can be a silicon dioxide layer. The passivation layer 56 can be any other suitable passivation layer, such as aluminum oxide, silicon carbide, aluminum nitride, silicon nitride, silicon oxynitride, or the like. The passivation layer 56 can include a dielectric material.

The passivation layers 26, 56 can have thicknesses that enable the BAW device 1 to have a higher order mode as a main mode. The passivation layer 26 can have a thickness of λ/2 and the passivation layer 56 can have a thickness of λ/2, where λ is a wavelength of a bulk acoustic wave generated by the BAW device in an operating mode. The passivation layer 56 has a thickness that is greater than a thickness of the first electrode 20 and/or a thickness of the second electrode 22. The thickness of the passivation layer 56 can be more than 3 times the thickness of the thickness of the first electrode 20 and/or the thickness of the second electrode 22. The thickness of the passivation layer 56 can be in a range from 1.5 to 6 times the thickness of the first electrode 20 and/or the thickness of the second electrode 22. In some embodiments, the thickness of the passivation layer 56 can be greater than a thickness of the piezoelectric layer 24. For example, the thickness of the passivation layer 56 can be in a range from 1 to 1.3 times the thickness of the piezoelectric layer 24. In the BAW device 2, an overtone mode can be excited as a main mode for a variety of combinations of layer thicknesses in a BAW material stack.

As with the BAW device 1 of FIGS. 1A and 1B, the frame structure 31 of the BAW device 2 can suppress the transverse mode and the engineered region 24e of the piezoelectric layer 24 can suppress the frame mode. The raised frame structure 32 can reduce or impede propagation of transverse mode.

In some applications, the main mode of the BAW device 2 of FIG. 2 can be a higher order than the main mode of the BAW device 1 of FIG. 1A. For example, the BAW device 2 can have a third order mode as a main mode, and the BAW device 1 can have a second order mode as a main mode. The third order mode can be referred to as a third overtone mode, and the second order mode can be referred to as a second overtone mode. In the BAW device 1 of FIG. 1A, the passivation layer 26 can contribute to exciting a second order mode as the main mode, while the passivation layers 26, 56 can contribute to exciting a third order mode as the main mode in the BAW device 2 of FIG. 2. In some other embodiments, one or more additional electrodes can be provided along with one or more additional layers in a BAW device to excite a higher order mode as the main mode.

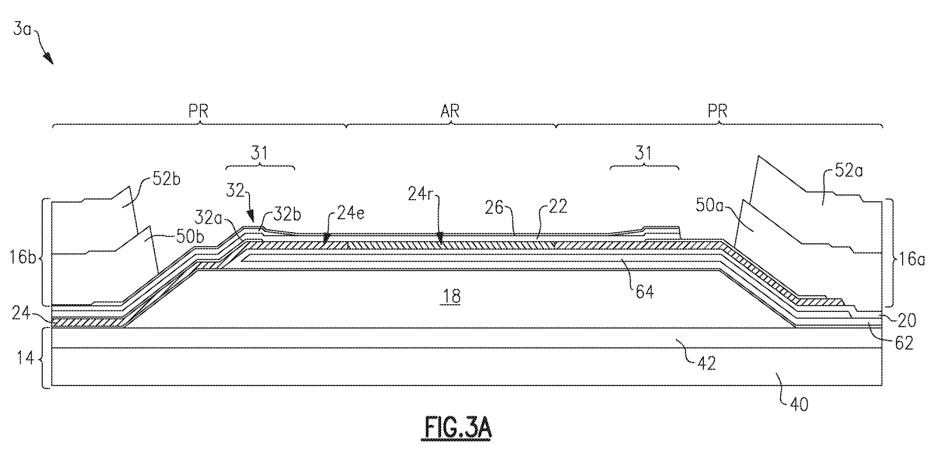

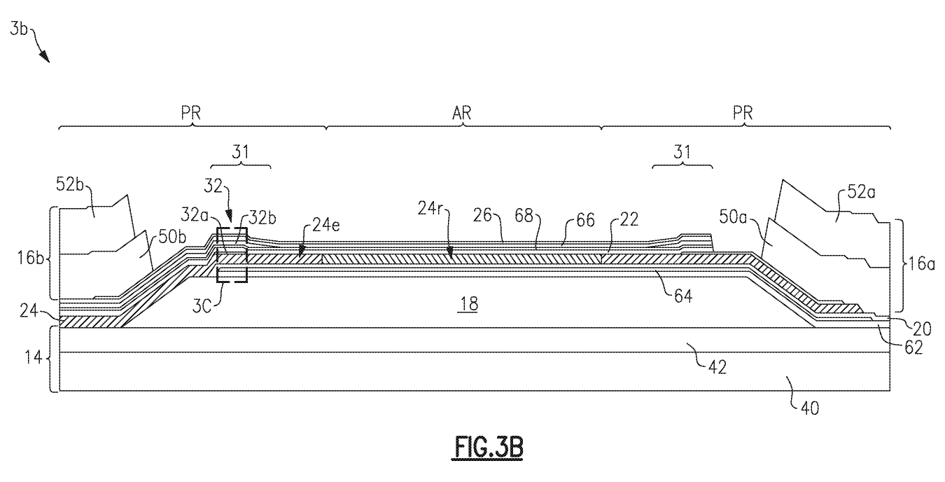

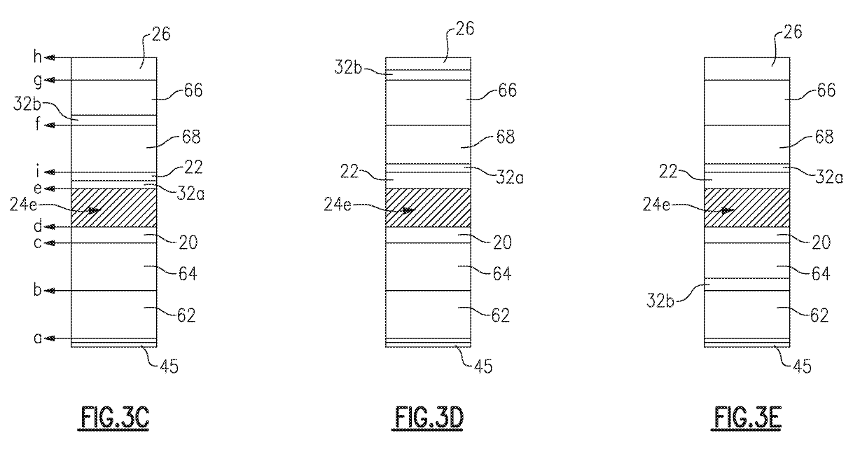

FIG. 3A is a schematic cross-sectional side view of a BAW device 3a according to an embodiment. Unless otherwise noted, the components of the BAW device 3a shown in FIG. 3A may be structurally and/or functionally the same as or generally similar to like components of other BAW devices disclosed herein. The BAW device 3a has a higher order mode as a main mode. In the BAW device 3a, a metal layer 62 and a Bragg reflector layer 64 contribute to exciting the overtone as the main mode. The metal layer 62 can be an electrode or an interposer. A BAW device can be electrically connected to another BAW device or other circuit element by way of an electrode. The electrode can be connected to a signal line or a voltage, such as ground. An input signal can be received at one electrode of the BAW device, and an output signal can be provided to another electrode of the BAW device. An interposer can be a layer that mechanically and/or electrically interfaces with a piezoelectric layer of a BAW device without being directly electrically connected to an element outside of the BAW device. The interposer can be at a floating voltage.

The BAW device 3a can include an acoustic reflector (e.g., a cavity 18), a first electrode 20, a second electrode 22, and a piezoelectric layer 24. The piezoelectric layer 24 includes an engineered region 24e. A region of the piezoelectric layer 24 that is not engineered to reduce its piezoelectricity can be referred to as a regular region 24r of the piezoelectric layer 24. A passivation layer 26 can be provided over the second electrode 22. The BAW device 3a can further include the metal layer 62 and the Bragg reflector layer 64. The metal layer 62 can be provided between the first electrode 20 and the cavity 18. The Bragg reflector layer 64 can be provided between the first electrode 20 and the metal layer 62.

The metal layer 62 can have a relatively high acoustic impedance. The metal layer 62 and/or the Bragg reflector layer 64 can include elemental metal or a metal alloy in some applications. The metal layer 62 can include molybdenum (Mo), tungsten (W), ruthenium (Ru), chromium (Cr), iridium (Ir), platinum (Pt), or any suitable alloy and/or combination thereof. The metal layer 62 can be formed of the same material as the first electrode 20 and/or the second electrode 22 in certain applications. In the BAW device 3a, the Bragg reflector layer 64 and the metal layer 62 can together function as an acoustic Bragg reflector layer on an electrode. Such a structure can reduce heat resistance and can improve heat conductivity. The materials of the metal layer 62 and the Bragg reflector layer 64 can include materials that can reduce the ohmic resistance in the BAW device 3a.

The Bragg reflector layer 64 can include any suitable low acoustic impedance material such that the Bragg reflector layer 64 and the metal layer 62 are alternating low acoustic impedance and high acoustic impedance layers. For example, the Bragg reflector layer 64 can be a titanium layer and the metal layer 62 can be a ruthenium layer. In some other applications, the Bragg reflector layer 64 can include a dielectric layer (e.g., a silicon dioxide layer) as a low acoustic impedance layer.

In the BAW device 3a, the first electrode 20 can be thinner than the second electrode 22. For example, the thickness of the first electrode 20 can be in a range between 30% to 70% or 40% to 60% of the thickness of the second electrode 22. The metal layer 62 can be thicker than the first electrode 20 and thicker than the second electrode 22. In some embodiments, the thickness of the metal layer 62 can be in a range between 1.2 to 2 times, 1.2 to 1.5 times, or 1.3 to 1.5 times the thickness of the second electrode 22. In some embodiments, the thickness of the metal layer 62 can be about λ/4. The Bragg reflector layer 64 can be thicker than the first electrode 20 and thicker than the second electrode 22. In some embodiments, the thickness of the Bragg reflector layer 64 can be in a range between 1.2 to 2 times, 1.2 to 1.5 times, or 1.3 to 1.5 times the thickness of the second electrode 22. In some embodiments, the thickness of the Bragg reflector layer 64 can be about λ/4. In embodiments where the metal layer 62 has a thickness of about λ/4 and the Bragg reflector layer has a thickness of about λ/4, the BAW device 3a can have a BAW device stack with a thickness of about 3λ/2. The combination of the metal layer 62 and the Bragg reflector layer 64 can reduce the ohmic resistance in the BAW device 3a. In some embodiments, additional pair of an electrode and a Bragg reflector layer can be included in a BAW device, for example, as shown in FIG. 3B. In certain applications, an acoustic Bragg reflector layer can be stacked with a second electrode 22 on an opposite side of a piezoelectric layer 24 than the cavity 18.

FIG. 3B is a schematic cross-sectional side view of a BAW device 3b according to an embodiment. Unless otherwise noted, the components of the BAW device 3b shown in FIG. 3B may be structurally and/or functionally the same as or generally similar to like components of other BAW devices disclosed herein. The BAW device 3b has a higher order mode as a main mode. In some applications, the main mode of the BAW device 3b can be a higher order than the main mode of the BAW device 3a. The main mode of the BAW device 3b can be a third order mode, and the main mode of the BAW device 3a can be a second order mode.

The BAW device 3b of FIG. 3B is generally similar to the BAW device 3a of FIG. 3A. Unlike the BAW device 3a, the BAW device 3b further includes a second metal layer 66 and a Bragg reflector layer 68. The second metal layer 66 can be an electrode or an interposer. The second metal layer 66 and the Bragg reflector layer 68 can be positioned between the second electrode 22 and the passivation layer 26. The second metal layer 66 can be positioned between the Bragg reflector layer 68 and the passivation layer 26 and the Bragg reflector layer 68 can be positioned between the second metal layer 66 and the second electrode 22. The second metal layer 66 can be structurally and/or functionally the same as or generally similar to the metal layer 62. The Bragg reflector layer 68 can be structurally and/or functionally the same as or generally similar to the Bragg reflector layer 64. The second metal layer 66 and/or the Bragg reflector layer 68 can include elemental metal or a metal alloy in some applications. In some embodiments, the thickness of the second metal layer 66 can be about λ/4 and the thickness of the Bragg reflector layer 68 can be about λ/4. The Bragg reflector layer 64 and the Bragg reflector layer 68 are examples of waveguide layers. The metal layer 62 and second metal layer 66 are examples of waveguide layers.

As with the BAW devices 1, 2 of FIGS. 1A, 1B and 2, the frame structure 31 can suppress the transverse mode and the engineered region 24e of the piezoelectric layer 24 can suppress the frame mode in the BAW devices 3a, 3b of FIGS. 3A and 3B. The raised frame structure 32 can reduce or impede propagation of transverse mode. The raised frame structure 32a and/or the raised frame structure 32b can be provided at any suitable locations in the stack of the BAW devices 3a, 3b in the peripheral region PR.

FIG. 3C is an enlarged view of a portion of a frame region in the peripheral region PR of the BAW device 3b of FIG. 3B. FIG. 3C shows a portion of an intermediate layer 45 (e.g., a seed layer and/or an adhesion layer), the metal layer 62 over the intermediate layer 45, the Bragg reflector layer 64 over the metal layer 62, the first electrode 20 over the Bragg reflector layer 64, the engineered region 24e of the piezoelectric layer 24 over the first electrode 20, a first raised frame structure 32a over the engineered region 24e, the second electrode 22 over the first raised frame structure 32a, the Bragg reflector layer 68 over the second electrode 22, a second raised frame structure 32b over the Bragg reflector layer 68, the second metal layer 66 over the second raised frame structure 32b, and the passivation layer 26 over the second metal layer 66. The first raised frame structure 32a can be an oxide raised frame layer. The second raised frame structure 32b can be a metal raised frame layer. One or more additional raised frame structures can be provided in the stack shown in FIG. 3C.

The raised frame structures 32a, 32b can be positioned at any suitable locations in the stack. For example, the first raised frame structure 32a and/or the second raised frame structure 32b can be positioned at one or more of location (a) between the intermediate layer 45 and the metal layer 62, (b) between the metal layer 62 and the Bragg reflector layer 64, (c) between the Bragg reflector layer 64 and the first electrode 20, (d) between the first electrode 20 and the engineered region 24e of the piezoelectric layer 24, (e) between the engineered region 24e of the piezoelectric layer 24 and the second electrode 22, (f) between the Bragg reflector layer 68 and the second metal layer 66, (g) between the second metal layer 66 and the passivation layer 26, (h) over the passivation layer 26, or (i) between the second electrode 22 and the Bragg reflector layer 68. In some embodiments, the metal layer 62 and/or the second metal layer 66 may be replaced with an electrically conductive non-metal layer.

FIG. 3D shows an example stack in a frame region of a BAW device. FIG. 3E shows another example stack in a frame region of a BAW device. Unless otherwise noted, the components shown in FIGS. 3D and 3E may be structurally and/or functionally the same as or generally similar to like components of other BAW devices disclosed herein. For example, the first raised frame structure 32a can be an oxide raised frame layer. As another example, the second raised frame structure 32b can be a metal raised frame layer. In FIG. 3D, the first raised frame structure 32a is provided between the second electrode 22 and the Bragg reflector layer 68 and the second raised frame structure 32b is provided between the second metal layer 66 and the passivation layer 26. In FIG. 3E, the first raised frame structure 32a is provided between the second electrode 22 and the Bragg reflector layer 68 and the second raised frame structure 32b is provided between the metal layer 62 and the Bragg reflector layer 64.

Any suitable principles and advantages disclosed herein can be implemented in any suitable BAW devices that have a higher order mode as a main mode. For example, the principles and advantages disclosed herein can be implemented in a BAW device that includes two or more piezoelectric layers and excites a higher order mode as a main mode.

In certain applications, a BAW device can include two piezoelectric layers stacked with each other between a pair of electrodes. The two piezoelectric layers can have c-axes oriented in a same direction. The BAW device can excite a third overtone mode as a main mode. The BAW device can include a metal layer between the two piezoelectric layers that is thicker than each of the electrodes of the pair of electrodes. The metal layer between the two piezoelectric layers can have a thickness of λ/2. The BAW device can include one or more raised frame layers in a frame region of the BAW device. The one or more raised frame layers can be positioned at any suitable interface between two different materials in a piezoelectric and electrode stack of the BAW device. One or both of the two piezoelectric layers can have an engineered region in a frame region of the BAW device. Any suitable combination of one or more engineered regions of the piezoelectric layers and raised frame layers in the frame region can be implemented.

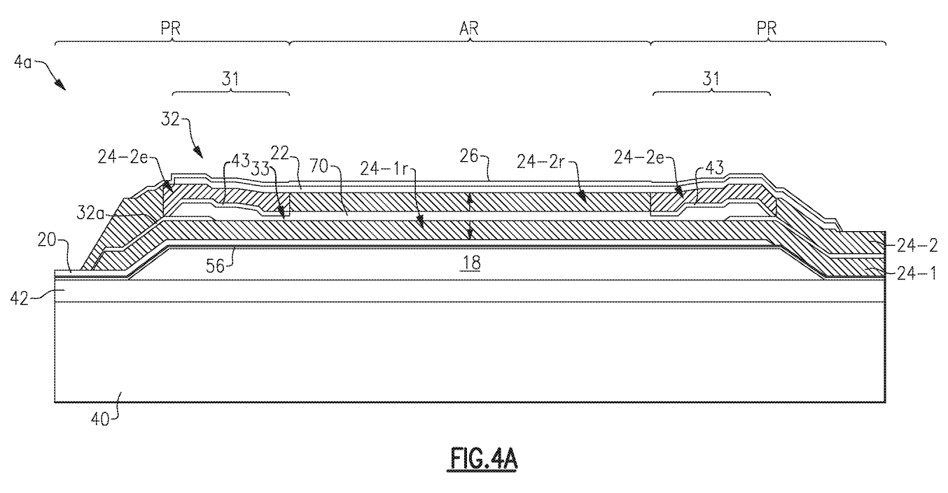

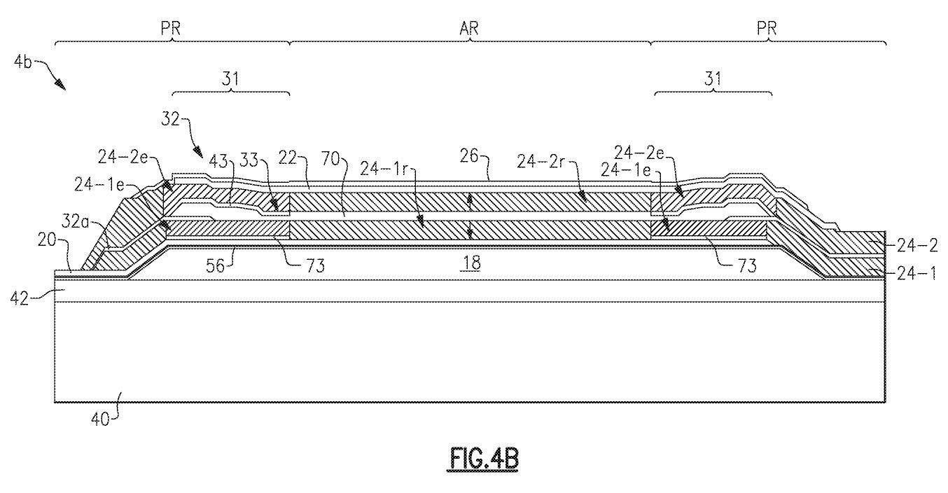

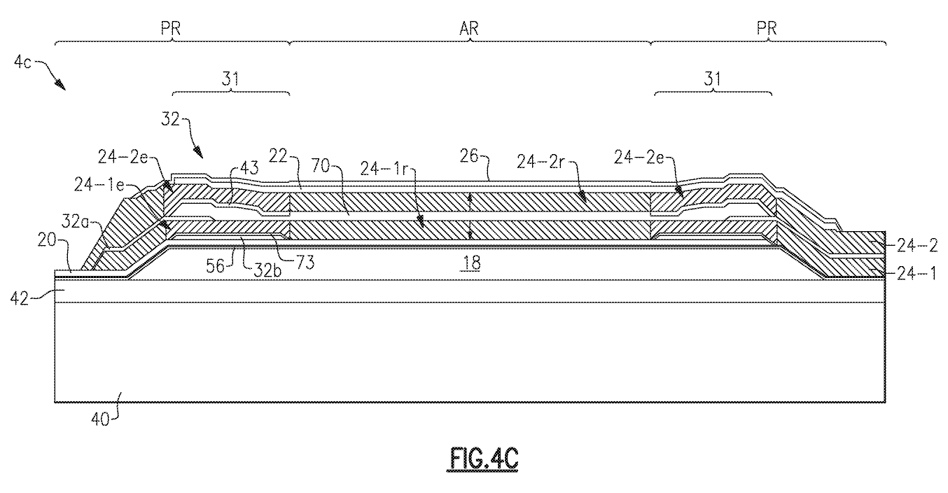

According to some applications, a BAW device can include two piezoelectric layers stacked with each other between two electrodes (see, for example, FIGS. 4A-4D). The two piezoelectric layers can have c-axes oriented in opposite directions. The BAW device can include one or more raised frame layers in a frame region of the BAW device. The one or more raised frame layers can be positioned at any suitable interface between two different materials in a piezoelectric and electrode stack of the BAW device. One or both of the two piezoelectric layers can have an engineered region in the frame region of the BAW device. Any suitable combination of one or more engineered regions of the piezoelectric layers and raised frame layers in the frame region can be implemented. The BAW device can excite a second overtone mode as a main mode.

FIG. 4A is a schematic cross-sectional side view of a BAW device 4a according to an embodiment. Unless otherwise noted, the components of the BAW device 4a shown in FIG. 4A may be structurally and/or functionally the same as or generally similar to like components of other BAW devices disclosed herein. The BAW device 4a has a higher order mode as a main mode.

The BAW device 4a can include an acoustic reflector (e.g., a cavity 18), a first electrode 20, a second electrode 22, a metal layer 70, a first piezoelectric layer 24-1, and a second piezoelectric layer 24-2. The second piezoelectric layer 24-2 includes an engineered region 24-2e. A region of the second piezoelectric layer 24-2 that is not engineered to reduce its piezoelectricity can be referred to as a regular region 24-2r of the second piezoelectric layer 24-2. In the BAW device 4a the first piezoelectric layer 24-1 is not engineered and includes a regular region 24-1r. A passivation layer 26 can be provided over the second electrode 22. In some embodiments, the metal layer 70 may be replaced with an electrically conductive non-metal layer. The BAW device 4a can further include a seed layer 43 positioned over portions of the metal layer 70 where the engineered region 24-2e is to be formed. The first piezoelectric layer 24-1 and the second piezoelectric layer 24-2 can have substantially opposite polarities making the BAW device 4a an example of a high even mode bulk acoustic wave (HEM-BAW) device or a double mode bulk acoustic wave (DM-BAW) device. The polarities of the first piezoelectric layer 24-1 and the second piezoelectric layer 24-2 are indicated by arrows in the middle of these layers. The polarities can correspond to c-axis orientations.

The BAW device 4a can include a frame region, where a frame structure 31 is positioned, outside of the main acoustically active region. The BAW device 4a can also include a peripheral region PR outside of the acoustically active region AR. The frame structure 31 of the BAW device 4a includes the raised frame structure 32 that overlaps with both the first electrode 20 and the second electrode 22. The second piezoelectric layer 24-2 in the peripheral region PR is engineered and the engineered region 24-2e of the second piezoelectric layer 24-2 has a lower magnitude effective piezoelectric coefficient than the regular region 24-2r of the second piezoelectric layer 24-2 in the acoustically active region AR. The frame region and the peripheral region PR can at least partially overlap. The frame region can be mostly or fully included within the peripheral region PR. For example, as shown in FIG. 4A, the frame region is within the peripheral region PR. In some embodiments, the engineered region 24-2e can extend the full length of the periphery region PR.

The first piezoelectric layer 24-1 and the second piezoelectric layer 24-2 can have different c-axis orientations so as to excite an overtone mode as a main mode for the BAW device. For example, the first piezoelectric layer 24-1 and the second piezoelectric layer 24-2 can have c-axes oriented in opposite directions. To manufacture c-axes with opposite direction growth, a seed layer can be provided, in some embodiments. The c-axis of the first piezoelectric layer 24-1 can be rotated about 180° relative to the c-axis of the second piezoelectric layer 24-2. The c-axis of the first piezoelectric layer 24-1 can be substantially opposite relative to the c-axis of the second piezoelectric layer 24-2. Such c-axes oriented in substantially opposite directions can be rotated by an angle in a range from 170° to 190° relative to each other. With opposite c-axis orientations, the first and second piezoelectric layers 24-1 and 24-2, respectively, can each excite an acoustic wave with an opposite phase. This can excite an overtone mode.

The frame structure 31 can include a raised frame structure 32 and/or a recessed frame structure 33. The raised frame structure 32 can reduce or impede propagation of the transverse mode. The raised frame structure 32 can include a raised frame structure 32a. The raised frame structure 32a can be positioned partially between the first piezoelectric layer 24-1 and the metal layer 70. The raised frame structure 32a can include a suitable dielectric material with a relatively high density. The density of the raised frame structure 32a can be similar to or heavier than the density of the first electrode 20, the second electrode 22, or the metal layer 70. The raised frame structure 32 can include a portion of the metal layer 70 that is thicker than the metal layer 70 in the acoustically active region AR. The recessed frame structure 33 can include a portion of the metal layer 70 that is thinner than the metal layer 70 in the acoustically active region AR. The metal layer 70 can include elemental metal or a metal alloy.

The engineered region 24-2e of the second piezoelectric layer 24-2 can suppress the frame mode associated with the raised frame structure 32. Having the raised frame structure 32 and the seed layer 43 between the first piezoelectric layer 24-1 and the second piezoelectric layer 24-2 can advantageously make the manufacturing process easier in some applications. The raised frame structure 32 can reduce lateral energy leakage from the main acoustically active region through the first piezoelectric layer 24-1 and/or the second piezoelectric layer 24-2, and the engineered region 24-2e of the second piezoelectric layer 24-2 can suppress the frame mode associated with the raised frame structure 32. The first piezoelectric layer 24-1 can also be engineered in some embodiments (see, for example, FIGS. 4B and 4C).

FIG. 4B is a schematic cross-sectional side view of a BAW device 4b according to an embodiment. FIG. 4C is a schematic cross-sectional side view of a BAW device 4c according to another embodiment. Unless otherwise noted, the components of the BAW devices 4b and 4c shown in FIGS. 4B and 4C, respectively, may be structurally and/or functionally the same as or generally similar to like components of other BAW devices disclosed herein. The BAW devices 4b, 4c have a higher order mode as a main mode. The BAW devices 4b and 4c are generally similar to the BAW device 4a of FIG. 4A, except that the BAW devices 4b and 4c have an engineered region in both the first piezoelectric layer 24-1 and the second piezoelectric layer 24-2.

Unlike the BAW device 4a, the BAW device 4b of FIG. 4B further includes a second seed layer 73 and the first piezoelectric layer 24-1 includes an engineered region 24-1e. The seed layer 73 can be implemented in accordance with any suitable principles and advantages discussed with reference to the seed layer 43. The engineered region 24-1e of the first piezoelectric layer 24-1 and the engineered region 24-2e of the second piezoelectric layer 24-2 can together suppress the frame mode associated with the raised frame structure 32. The engineered region 24-1e of the first piezoelectric layer 24-1 can provide further suppression of the frame mode associated with the frame structure 31 as compared to the BAW device 4a.

The BAW device 4c of FIG. 4C can include a frame structure 31 that includes a raised frame structure 32 having a raised frame structure 32a and a raised frame structure 32b. The raised frame structure 32a can be positioned partially between the first piezoelectric layer 24-1 and the metal layer 70, and the raised frame structure 32b can be positioned partially between the first electrode 20 and the first piezoelectric layer 24-1. The raised frame structure 32a and/or the raised frame structure 32b can include a material that has a relatively high mass density. The raised frame structure 32a and/or the raised frame structure 32b can include a suitable dielectric material with a relatively high density. The density of the raised frame structure 32a can be similar to or heavier than the density of the first electrode 20, the second electrode 22, or the metal layer 70. The raised frame structure 32b can contribute to further suppressing the transverse mode as compared to the frame structure 31 that includes only the raised frame structure 32a.

One or more raised frame structures can be provided at any suitable location(s) in the BAW devices 4a, 4b, 4c. For example, a raised frame structure can be positioned (1) between the cavity 18 and the first electrode 20, (2) between the first electrode 20 and the first piezoelectric layer 24-1, (3) between the first piezoelectric layer 20-1 and the metal layer 70, (4) between the metal layer 70 and the second piezoelectric layer 24-2, (5) between the second piezoelectric layer 24-2 and the second electrode 22, (6) over the second electrode 22, or any suitable combination thereof. One or more suitable portions of the first piezoelectric layer 24-1 and/or the second piezoelectric layer 24-2 can be engineered to suppress the transverse mode associated with the one or more raised frame structures in a HEM-BAW device. In an embodiment (not illustrated), a BAW device can be like the BAW devices 4b or 4c, except that the first piezoelectric layer 24-1 can include an engineered region 24-1e and the second piezoelectric layer 24-2 can be without an engineered region.

Although FIGS. 4A-4C show embodiments having two piezoelectric layers and three electrodes/interposers, any suitable principles and advantages disclosed herein can be implemented in a BAW device that include three or more piezoelectric layers and four or more electrodes/interposers. Also, HEM-BAW or DM-BAW devices disclosed herein can be configured to be FBARs or SMRs, in some applications.

The metal layer 70 can be an electrode or an interposer. FIGS. 4A-4C show embodiments of a HEM-BAW or DM-BAW device in which the polarities of the first piezoelectric layer 24-1 and the second piezoelectric layer 24-2 of the BAW devices 4a, 4b, 4c are opposite. In these embodiments, the first electrode 20 and the second electrode 22 can be coupled to a signal line of a filter or a voltage source, and the metal layer 70 can be a floating layer. Such a configuration can be referred to as a stacked piezoelectric cascade BAW device. The metal layer 70 can be referred to as an interposer when configured as a floating layer. In some other cases, a BAW device can be a stacked split BAW where the first electrode 20, the second electrode 22, and the metal layer 70 are each coupled to an external connection. In some configurations, the first electrode 20 and the second electrode 22 can be coupled to ground and the metal layer 70 can be coupled to the signal line. In some other configurations, the first electrode 20 and the second electrode 22 can be coupled to a signal line and the metal layer 70 can be coupled to ground. The metal layer 70 can be referred to as an electrode when not floating. For example, the metal layer can be referred to as an electrode when coupled to a signal line or ground.

In some embodiments, the second piezoelectric layer 24-2 can be provided over the first piezoelectric layer 24-1 without the metal layer 70 positioned therebetween, for example, as illustrated in FIG. 4D. FIG. 4D is a schematic cross-sectional side view of a BAW device 4d according to an embodiment. Unless otherwise noted, the components of the BAW device 4d shown in FIG. 4D may be structurally and/or functionally the same as or generally similar to like components of other BAW devices disclosed herein. The BAW device 4d has a higher order mode as a main mode. The BAW device 4d is generally similar to the BAW device 4b of FIG. 4B, except that the BAW device 4d does not include the metal layer 70 between the first piezoelectric layer 24-1 and the second piezoelectric layer 24-2. In some embodiments, there can be a seed layer (not shown) between the regular region 24-1r of the first piezoelectric layer 24-1 and the regular region 24-2r of the second piezoelectric layer 24-2. Such a seed layer can cause the c-axis of the second piezoelectric layer 24-2 in the regular region 24-2r to be orientated in an opposite direction as the c-axis of the first piezoelectric layer 24-1 the regular region 24-1r.

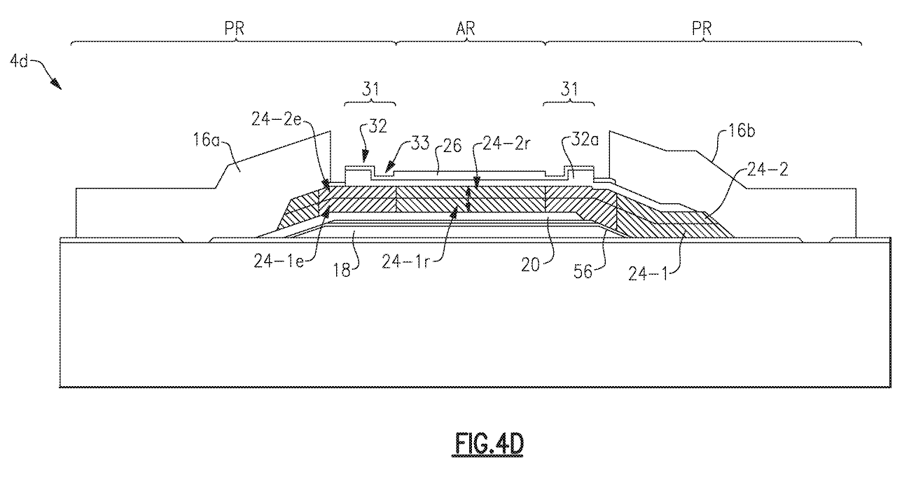

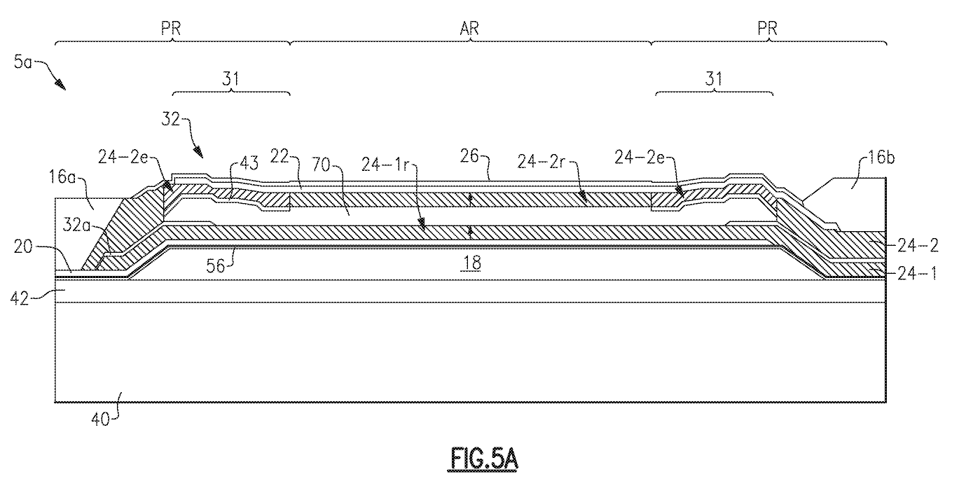

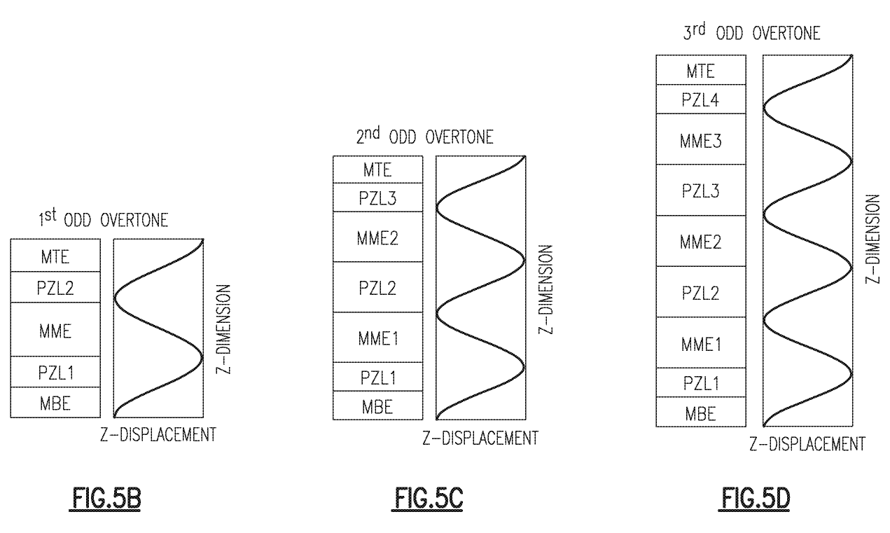

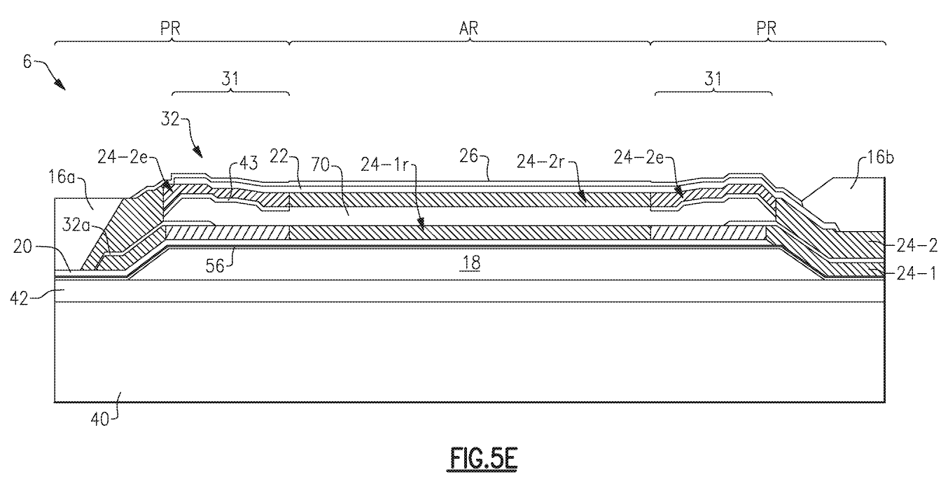

In some other embodiments, a BAW device can be a high odd mode bulk acoustic wave (HOM-BAW) device that can include a first piezoelectric layer 24-1 and a second piezoelectric layer 24-2 that have the same polarity (see, for example, FIG. 5A).

FIG. 5A is a schematic cross-sectional side view of a BAW device 5a according to an embodiment. Unless otherwise noted, the components of the BAW device 5a shown in FIG. 5A may be structurally and/or functionally the same as or generally similar to like components of other BAW devices disclosed herein. The BAW device 5a has a higher order mode as a main mode.

Unlike the BAW devices 4a, 4b, 4c, the polarity of the first piezoelectric layer 24-1 and the polarity of the second piezoelectric layer 24-2 in the BAW device 5a are substantially the same. The BAW device 4a is an example of a HOM-BAW device. In the BAW device 4a, the first electrode 20 and the second electrode 22 can be coupled to a signal line of a filter or a voltage source, and the metal layer 70 can be a floating layer. A metal layer 70 that is a floating layer can be referred to as an interposer. In some other configurations, the first electrode 20 and the second electrode 22 can be coupled to ground and the metal layer 70 can be coupled to the signal line. A metal layer 70 that is coupled to a signal line or a voltage, such as ground, can be referred to as an electrode. The polarities of the first piezoelectric layer 24-1 and the second piezoelectric layer 24-2 are indicated by arrows in the middle of these layers. The polarities can correspond to c-axis orientations.

In the BAW device 5a thicknesses of the first electrode 20, the first piezoelectric layer 24-1, the second electrode 22, the second piezoelectric layer 24-2, and the metal layer 70 can be selected and/or optimized to excite an overtone mode. The metal layer 70 in the BAW device 5a can be thicker than the metal layer 70 in the BAW devices 4a, 4b, 4c, and the first and second piezoelectric layers 24-1, 24-2 of the BAW device 5a can be thinner than the first and second piezoelectric layers 24-1, 24-2 of the BAW devices 4a, 4b, 4c. For example, the thickness of the metal layer 70 of the BAW device 5a can be in a range between 250 micrometers (μm) and 550 μm, 300 μm and 500 μm, or 320 μm and 340 μm, while the thickness of the metal layer 70 of the BAW devices 4a, 4b, 4c can be in a range between 5 μm and 40 μm, 10 μm and 30 μm, or 15 μm and 25 μm. For example, the thickness of the first and/or second piezoelectric layer(s) 24-1, 24-2 in the BAW device 5a can be in a range between 40 μm and 110 μm, 60 μm and 90 μm, or 70 μm and 80 μm, while the thickness of the first and/or second piezoelectric layer(s) 24-1, 24-2 in the BAW devices 4a, 4b, 4c can be in a range of 100 μm and 240 μm, 130 μm and 210 μm, or 160 μm and 180 μm. In some embodiments, the first electrode 20 and the metal layer 70 of the BAW device 5a can be thinner than the first electrode 20 and the metal layer 70 of the BAW devices 4a, 4b, 4c.

The BAW device 5a can also include a first interconnect structure 16a and a second interconnect structure 16b. The first interconnect structure 16a can include one or more conductive layers, and the second interconnect structure 16b can include one or more conductive layers.

As with the BAW devices 4a, 4b, 4c, one or more raised frame structures can be provided at any suitable location(s) in the BAW device 5a. For example, a raised frame structure can be positioned (1) between the cavity 18 and the first electrode 20, (2) between the first electrode 20 and the first piezoelectric layer 24-1, (3) between the first piezoelectric layer 24-1 and the metal layer 70, (4) between the metal layer 70 and the second piezoelectric layer 24-2, (5) between the second piezoelectric layer 24-2 and the second electrode 22, (6) over the second electrode 22, or any suitable combination thereof. One or more suitable portions of the first piezoelectric layer 24-1 and/or the second piezoelectric layer 24-2 in a HOM-BAW device can be engineered to suppress a frame mode associated with the one or more raised frame structures.

FIG. 5B is a diagram showing a theoretical wave displacement in the BAW device 5a. In FIG. 5B, a metal bottom electrode (MBE) corresponds to the first electrode 20, a first piezoelectric layer (PZL1) corresponds to the first piezoelectric layer 24-1, a middle metal electrode (MME) corresponds to the metal layer 70, a second piezoelectric layer (PZL2) corresponds to the second piezoelectric layer 24-2, and a metal top electrode (MTE) corresponds to the second electrode 22. FIG. 5B shows that the first odd overtone (e.g., (3λ)/2) is generated in the BAW device 5a. The first odd overtone can be a third harmonic of a fundamental mode which can be the third overtone mode. One or more additional piezoelectric layers and one or more additional electrodes can be included in a BAW device to generate the second or more odd overtone modes.

FIG. 5C is a diagram showing a theoretical wave displacement in a BAW device that includes four electrodes and three piezoelectric layers therebetween. The BAW device shown in FIG. 5C includes a metal bottom electrode (MBE), a first piezoelectric layer (PZL1), a first middle metal electrode (MME1), a second piezoelectric layer (PZL2), a second middle metal electrode (MME2), a third piezoelectric layer (PZL3), and a metal top electrode (MTE). Any other suitable metal layer can implement MME1 and/or MME2. FIG. 5C shows that the second odd overtone (e.g., (5λ)/2) is generated in the BAW device. The second odd overtone can be a fifth harmonic of a fundamental mode which can be the fifth overtone mode. The polarities or the c-axes of the first to third piezoelectric layers PZL1, PZL2, PZL3 can be substantially the same.

FIG. 5D is a diagram showing a theoretical wave displacement in a BAW device that includes five electrodes and four piezoelectric layers therebetween. The BAW device shown in FIG. 5C includes a metal bottom electrode (MBE), a first piezoelectric layer (PZL1), a first middle metal electrode (MME1), a second piezoelectric layer (PZL2), a second middle metal electrode (MME2), a third piezoelectric layer (PZL3), a third middle metal electrode (MME3), a fourth piezoelectric layer (PZL4), and a metal top electrode (MTE). Any other suitable metal layer can implement MME1 and/or MME2 and/or MME3. FIG. 5D shows that the third odd overtone (e.g., (7 λ)/2) is generated in the BAW device. The third odd overtone can be a seventh harmonic of a fundamental mode which can be the seventh overtone mode. The polarities or the c-axes of the first to fourth piezoelectric layers PZL1, PZL2, PZL3, PZL4 can be substantially the same.

FIG. 5E is a schematic cross-sectional side view of a BAW device 6 according to an embodiment. Unless otherwise noted, the components of the BAW device 6 shown in FIG. 5E may be structurally and/or functionally the same as or generally similar to like components of other BAW devices disclosed herein. The BAW device 6 has a higher order mode as a main mode. The BAW device 6 can be an HOM-BAW, an HEM-BAW, or a DM-BAW. The BAW device 6 is generally similar to the BAW device 5a of FIG. 5A or the BAW device 4a of FIG. 4A, except that the BAW device 6 has an engineered region in both the first piezoelectric layer 24-1 and the second piezoelectric layer 24-2.

In some applications, the first electrode 20, the second electrode 22, or the metal layer 70 can be electrically coupled to, for example, a signal line, a voltage source, or ground. FIG. 5F shows an end portion of a BAW device according to some embodiments. FIG. 5G shows a different end portion of a BAW device according to some embodiments. The configurations shown in FIGS. 5F and 5G can be applied in any suitable manner to the BAW devices disclosed herein that include the first electrode 20, the second electrode 22, and the metal layer 70. For example, the right side of the BAW device 6 in FIG. 5E can have the end portion shown in FIG. 5F and the left side of the BAW device 6 in FIG. 5E can have the end portion shown in FIG. 5G, in some cases. For example, the right side of the BAW device 6 can be positioned in a location within the peripheral region PR and the left side of the BAW device 6 can be positioned in an opposite location in the peripheral region PR as seen in a top plan view (see, for example, FIG. 1B). In some other cases, the connections for the first electrode 20 and the second electrode 22 can be on opposing sides as shown in, for example, FIG. 5E, and the connection for the metal layer 70 shown in the end portion shown in FIG. 5G can be perpendicular in the plan view to the connections for the first electrode 20 and the second electrode 20.

The first electrode 20 and the second electrode 22 can be coupled to a signal line, a voltage source, or ground in the end portion shown in FIG. 5F. In the example shown in FIG. 5F, the first electrode 20 and the second electrode 22 are electrically coupled to one another. In some other applications, the first electrode 20 and the second electrode 22 can be electrically isolated and/or connected to different circuit elements and/or voltages. The metal layer 70 can be coupled to a signal line, a voltage source, or ground in the end portion shown in FIG. 5G.

The BAW devices with different structures disclosed herein can have different advantages, and a suitable type of a BAW device can be selected based on the application of the BAW device. For example, a suitable BAW device can be selected based on the band in which the BAW device operates. Certain BAW devices disclosed herein can be more beneficial for a high band application and/or an ultra-high band application. Certain BAW devices disclosed herein can reduce the resonator size, for example, by a factor of two or four. The size reduction can be a reduction in area consumed by a BAW device. Certain BAW devices disclosed herein can improve ruggedness.

In some embodiments, the principles and advantages disclosed herein can be implemented in a BAW device that includes an acoustic reflector (e.g., a cavity 18), a first electrode, a second electrode, a metal layer, a first piezoelectric layer, and a second piezoelectric layer. At least one of the first and second piezoelectric layers include an engineered region in a frame region in which a frame structure is provided. A region of the piezoelectric layer that is not engineered to reduce its piezoelectricity can be referred to as a regular region of the piezoelectric layer. The first piezoelectric layer can have a first c-axis and the second piezoelectric layer can have a second c-axis. In some embodiments, the first c-axis and the second c-axis can be oriented in substantially opposite directions.

BAW devices disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, base stations, repeaters, relays, wireless communication infrastructure, access points, customer premises equipment (CPE), and distributed antenna systems. BAW oscillators can replace crystal oscillators in a variety of applications, such as but not limited to electronic timing products. In some applications, an oscillator that includes a BAW resonator can be implemented together with a crystal oscillator.

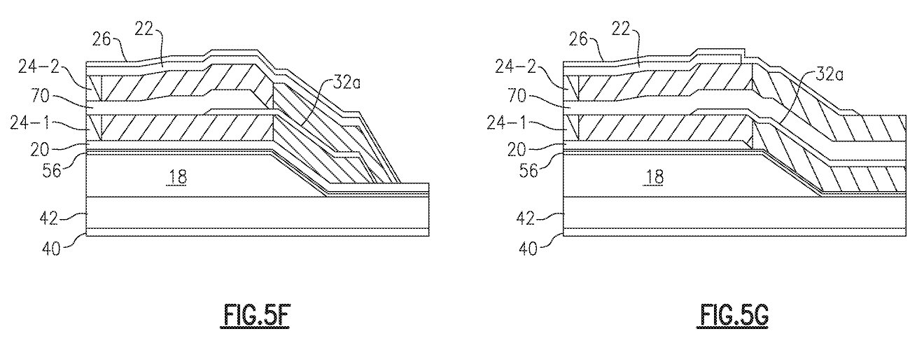

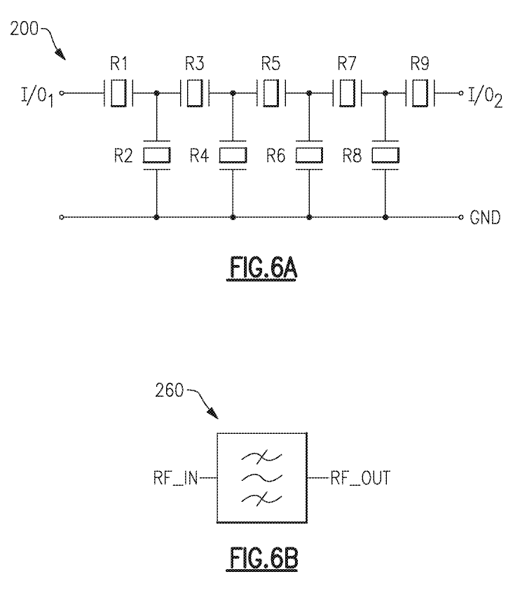

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 6A.

FIG. 6A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio – Dual Connectivity (ENDC) application. A multiplexer including any such filters can include one or more other filters with a passband corresponding to a 5G NR operating band and/or a 4G LTE operating band. A filter that includes a BAW resonator in accordance with any suitable principles and advantages disclosed herein can be arranged to filter a radio frequency signal in any other suitable operating band, such as a WiFi operating band, a Global Positioning System (GPS) operating band, a Bluetooth operating band, a ZigBee operating band, a WiMax operating band, etc.

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 6B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

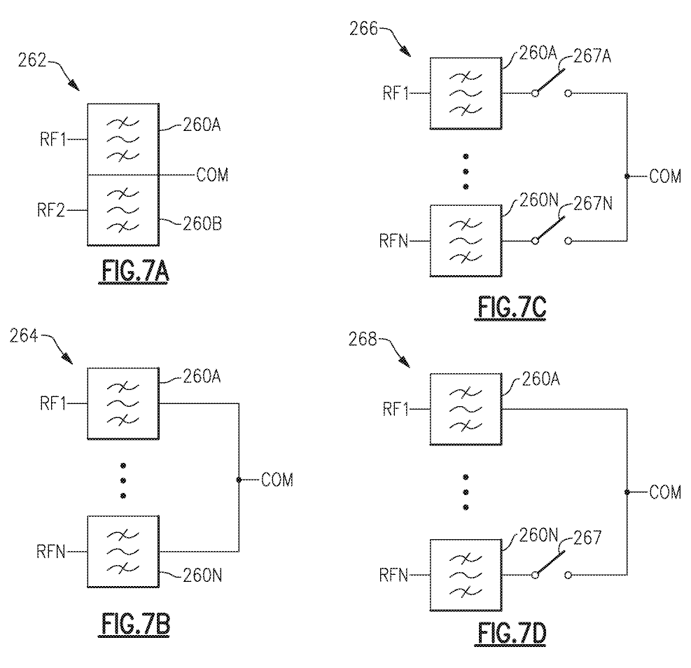

The BAW devices disclosed herein can be implemented in a standalone filter and/or in a filter of any suitable multiplexer. Such filters can be any suitable topology, such as a ladder filter topology. The filter can be a band pass filter arranged to filter a radio frequency signal in a 4G LTE band and/or 5G NR band. The filter can be a band pass filter having a passband corresponding to an operating band of any other suitable standard, such as WiFi, etc. Example multiplexers will be discussed with reference to FIGS. 7A to 7D. Any suitable principles and advantages of these multiplexers can be implemented together with each other.

FIG. 7A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 7B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 7C is a schematic diagram of a multiplexer 266 that includes an acoustic wave filter according to an embodiment. The multiplexer 266 is like the multiplexer 264 of FIG. 7B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 7D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 8,9, and 10, are schematic block diagrams of illustrative packaged modules according to certain embodiments. Any suitable combination of features of these packaged modules can be implemented with each other.

FIG. 8 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 8 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 8. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

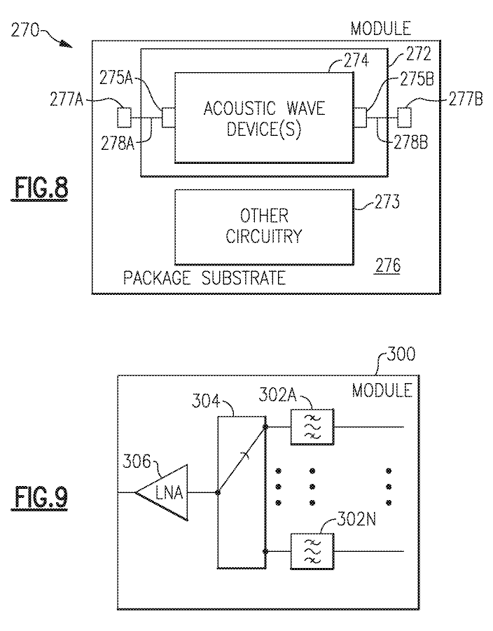

FIG. 9 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

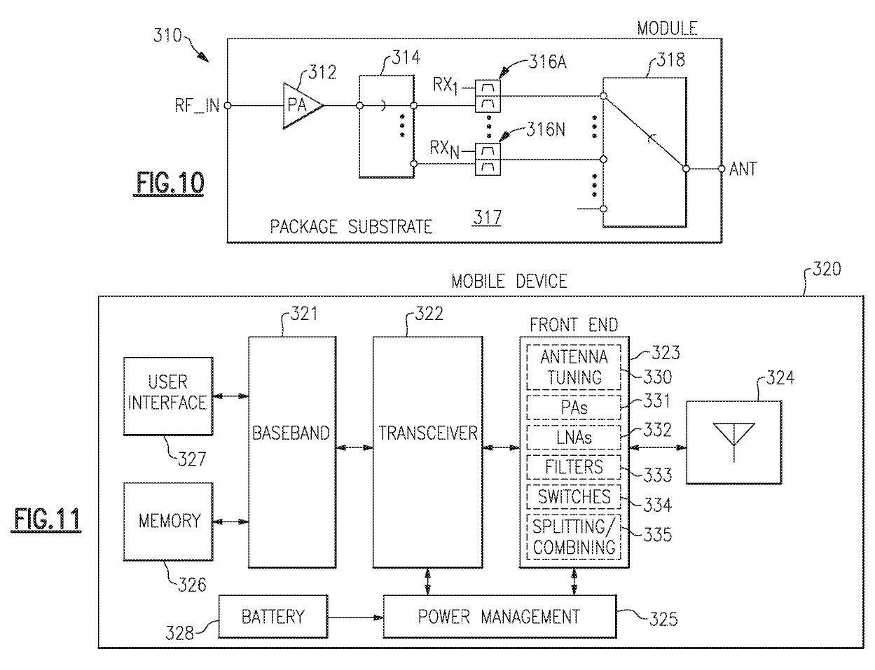

FIG. 10 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 10 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 10 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

The BAW devices disclosed herein can be implemented in wireless communication devices. FIG. 11 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 11 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 11, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 11, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, in a frequency range from 5 GHz to 20 GHz, or in a range from 12 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having a main acoustically active region and a frame region, the bulk acoustic wave device having a higher order mode as a main mode, and the bulk acoustic wave device comprising:
a frame structure in the frame region;
electrodes including a first electrode and a second electrode; and
a piezoelectric layer positioned between the first electrode and the second electrode in the main acoustically active region and the frame region, the piezoelectric layer having an engineered region in at least part of the frame region, and the piezoelectric layer contributing to exciting the higher order mode as the main mode.

2. The bulk acoustic wave device of claim 1 further comprising a waveguide layer at least in the main acoustically active region.

3. The bulk acoustic wave device of claim 2 wherein the waveguide layer has a thickness of λ/2, and λ is a wavelength of a bulk acoustic wave generated by the bulk acoustic wave device in an operating mode.

4. The bulk acoustic wave device of claim 2 wherein the waveguide layer includes a passivation layer.

5. The bulk acoustic wave device of claim 4 further comprising a second passivation layer, the first electrode is positioned between the piezoelectric layer and the second passivation layer, and the second electrode is positioned between the piezoelectric layer and the passivation layer.

6. The bulk acoustic wave device of claim 4 wherein a thickness of the passivation layer is in a range from 1.5 to 4 times a thickness of the second electrode.

7. The bulk acoustic wave device of claim 2 wherein the waveguide layer includes a Bragg reflector layer.

8. The bulk acoustic wave device of claim 7 further comprising a metal layer, the Bragg reflector layer is positioned between the first electrode and the metal layer, and the first electrode is positioned between the piezoelectric layer and the Bragg reflector layer.

9. The bulk acoustic wave device of claim 1 further comprising a second piezoelectric layer at least in the main acoustically active region.

10. The bulk acoustic wave device of claim 9 further comprising a metal layer positioned between the piezoelectric layer and the second piezoelectric layer.

11. The bulk acoustic wave device of claim 9 wherein the piezoelectric layer has a first c-axis and the second piezoelectric layer has a second c-axis, and the first c-axis and the second c-axis are oriented in substantially opposite directions.

12. The bulk acoustic wave device of claim 9 wherein the piezoelectric layer has a first c-axis and the second piezoelectric layer has a second c-axis, the first c-axis and the second c-axis have a same orientation.

13. The bulk acoustic wave device of claim 9 wherein the second piezoelectric layer has a second engineered region in the frame region.

14. The bulk acoustic wave device of claim 1 wherein the higher order mode is a second overtone mode.

15. The bulk acoustic wave device of claim 1 wherein the higher order mode is a third overtone mode.

16. The bulk acoustic wave device of claim 1 wherein the piezoelectric layer has an effective piezoelectric coefficient in the engineered region that is less than 50% of a magnitude of an effective piezoelectric coefficient of the piezoelectric layer in the main acoustically active region.

17. The bulk acoustic wave device of claim 1 comprising a seed layer positioned between the first electrode and the engineered region of the piezoelectric layer, the bulk acoustic wave device being free from the seed layer in the main acoustically active region.

18. An acoustic wave filter for filtering a radio frequency signal, the acoustic wave filter comprising:
a bulk acoustic wave resonator having a frame region and a main acoustically active region, the bulk acoustic wave resonator including a frame structure in the frame region, electrodes including a first electrode and a second electrode, and a piezoelectric layer positioned between the first electrode and the second electrode in the main acoustically active region and the frame region, the piezoelectric layer having an engineered region in at least part of the frame region, and the piezoelectric layer contributing to exciting a higher order mode as a main mode of the bulk acoustic wave resonator; and
a plurality of additional acoustic wave resonators, the bulk acoustic wave resonator and the plurality of additional acoustic wave resonators configured to filter the radio frequency signal.

19. The acoustic wave filter of claim 18 wherein the acoustic wave filter is a bandpass filter, and the radio frequency signal has a frequency in a range from 5 gigahertz to 12 gigahertz.

20. A wireless communication device comprising:
a radio frequency front end including a filter that includes a bulk acoustic wave resonator having a frame region and a main acoustically active region, the bulk acoustic wave resonator including a frame structure in the frame region, electrodes including a first electrode and a second electrode, and a piezoelectric layer positioned between the first electrode and the second electrode in the main acoustically active region and the frame region, the piezoelectric layer having an engineered region in at least part of the frame region, and the piezoelectric layer contributing to exciting a higher order mode as a main mode of the bulk acoustic wave resonator;
an antenna coupled to the radio frequency front end;
a transceiver in communication with the radio frequency front end; and
a baseband system in communication with the transceiver.
